(19) United States
(12) Patent Application Publication
(10) Pub. No.: US 2007/0017569 A1
(43) Pub. Date: Jan. 25, 2007

(54) Metal complex compositions and use thereof in dye sensitized solar cells

(75) Inventors: John Yupeng Gui, Niskayuna, NY (US); Oltea Puica Siclovan, Rexford, NY (US); Mukundan Thelakkat, Bayreuth (DE); James Lawrence Spivack, Cobleskill, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company

(21) Appl. No.: 11/188,575

(22) Filed: Jul. 25, 2005

(51) Int. Cl. C07F 15/00; H01L 31/00

(52) U.S. Cl. 136/256; 546/2; 257/40

(57) ABSTRACT

The present invention provides in one aspect a composition having at least one metal complex, such that the metal complex comprises at least one metal atom, at least one first organic ligand comprising at least one triarylamine group, at least one second ligand comprising at least one acidic group, and at least one thiocyanate or isothiocyanate ligand. This composition may be disposed on a semiconductor layer which is further disposed on an electrically conductive surface to provide a dye-sensitized electrode. The dye-sensitized electrode can be assembled together with a counter electrode and a redox electrolyte to provide a dye-sensitized solar cell.

### BACKGROUND

The invention includes embodiments that relate to compositions comprising metal complexes. The invention also includes embodiments that relate to dye-sensitized electrodes and dye-sensitized solar cells that may be produced using the above composition.

The dyes or sensitizers are a key feature of the dye-sensitized solar cells (DSSC) that have great potential for future photovoltaic applications owing to their potentially low production cost. The central role of the dyes is the efficient absorption of light and its conversion to electrical energy. In order for the dyes to provide high efficiency, solar radiation over as broad a spectrum as possible has to be absorbed. Further, ideally, every absorbed photon should be converted to an electron resulting from an excited dye state. In order for the dye to be returned to its initial state, ready for absorption of another photon, it has to accept an electron from the hole transport material. To ensure many turnovers and a long useful life of the device, both electron injection into the electron transport material and hole injection into the hole transport material has to be faster than any other chemistry that the dye is subject to. Furthermore, it is important that the dyes do not recapture electrons injected into the electron transport material or serve as an electronic pathway from the electron transport material to the hole transport material.

Particularly desirable would be dyes with high power efficiencies for applications in DSSCs. Organic dyes capable of absorbing a broad range of wavelengths in the solar spectrum as well as having strong absorptivity represent an attractive but elusive goal, since the light absorption characteristics of most organic materials cannot be predicted reliably and must be determined experimentally. Efforts to improve dye performance in DSSCs have focused on increasing the thickness of the TiO₂ film component on which the dye is adsorbed thereby increasing the surface area available for dye adsorption. However, as a result of increasing the TiO₂ film thickness in the DSSC, the transport distance for the photo-generated electron increases, thereby increasing the possibility of unproductive back reactions.

Therefore, there is a need for dyes that absorb radiation over a broad range of the solar spectrum and have strong absorptivity. Moreover, it is very desirable to provide energy efficient solar cells that can take advantage of dyes that can absorb over a broad range and have high absorptivity values.

### BRIEF DESCRIPTION

In one embodiment, the present invention provides a composition comprising at least one metal complex, such that the metal complex comprises at least one metal atom, at least one first organic ligand comprising at least one triarylamine group, at least one second ligand comprising at least one acidic group, and at least one thiocyanate or isothiocyanate ligand.

In another embodiment, the present invention provides a dye-sensitized electrode comprising a substrate having an electrically conductive surface, an electron transporting layer that is disposed on the electrically conductive surface, and a composition comprising at least one metal complex disposed on the electron transporting layer. The metal complex comprises at least one metal atom, at least one first organic ligand comprising at least one triarylamine group, at least one second ligand comprising at least one acidic group, and at least one thiocyanate or isothiocyanate ligand.

In yet another embodiment, the present invention provides a dye-sensitized solar cell comprising a dye sensitized electrode, the dye sensitized electrode comprising a substrate having an electrically conductive surface, an electron transporting layer that is disposed on the electrically conductive surface, and a composition comprising at least one metal complex disposed on the electron transporting layer; a counter electrode; and a hole transporting layer in contact with the dye-sensitized electrode and the counter electrode. The metal complex comprises at least one metal atom, at least one first organic ligand comprising at least one triarylamine group, at least one second ligand comprising at least one acidic group, and at least one thiocyanate or isothiocyanate ligand.

### BRIEF DESCRIPTION OF THE DRAWINGS

FIG. 1 presents a reaction scheme for the preparation of a first organic ligand used in the preparation of the metal complex dye compositions of the present invention.

FIG. 2 presents a reaction scheme for the preparation of the metal complex dye compositions of the present invention.

### DETAILED DESCRIPTION

In the following specification and the claims which follow, reference will be made to a number of terms which shall be defined to have the following meanings.

The singular forms “a”, “an” and “the” include plural referents unless the context clearly dictates otherwise.

As used herein, the term “aromatic radical” refers to an array of atoms having a valence of at least one comprising at least one aromatic group. The array of atoms having a valence of at least one comprising at least one aromatic group may include heteroatoms such as nitrogen, sulfur, selenium, silicon and oxygen, or may be composed exclusively of carbon and hydrogen. As used herein, the term “aromatic radical” includes but is not limited to phenyl, pyridyl, furanyl, thienyl, naphthyl, phenylene, and biphenyl radicals. As noted, the aromatic radical contains at least one aromatic group. The aromatic group is invariably a cyclic structure having 4n+2 “delocalized” electrons where “n” is an integer equal to 1 or greater, as illustrated by phenyl groups (n=1), thienyl groups (n=1), furanyl groups (n=1), naphthyl groups (n=2), azulenyl groups (n=2), anthraceneyl groups (n=3) and the like. The aromatic radical may also include nonaromatic components. For example, a benzyl group is an aromatic radical which comprises a phenyl ring (the aromatic group) and a methylene group (the nonaromatic component). Similarly a tetrahydronaphthyl radical is an aromatic radical comprising an aromatic group (C₆H₃) fused to a nonaromatic component —(CH₂)₄—. For convenience, the term “aromatic radical” is defined herein to encompass a wide range of functional groups such as alkyl groups, alkenyl groups, alkynyl groups, haloalkyl groups, haloaromatic groups, conjugated dienyl groups, alcohol groups, ether groups, aldehydes groups, ketone groups, carboxylic acid groups, acyl groups (for example carboxylic acid derivatives such as esters and amides), amine groups, nitro groups, and the like. For example, the 4-methylphenyl radical is a C₇ aromatic radical comprising a methyl group, the methyl group being a functional group which is an alkyl group. Similarly, the 2-nitrophenyl group is a C₆ aromatic radical comprising a nitro group, the nitro group being a functional group. Aromatic radicals include halogenated aromatic radicals such as 4-trifluoromethylphenyl, hexafluoroisopropylidenebis(4-phen-1-yloxy) (i.e., —OPhC(CF₃)₂PhO—), 4-chloromethylphen-1-yl, 3-trifluorovinyl-2-thienyl, 3-trichloromethylphen-1-yl (i.e., 3-CCl₃Ph-), 4-(3-bromoprop-1-yl)phen-1-yl (i.e., 4-BrCH₂CH₂CH₂Ph-), and the like. Further examples of aromatic radicals include 4-allyloxyphen-1-oxy, 4-aminophen-1-yl (i.e., 4-H₂NPh-), 3-aminocarbonylphen-1-yl (i.e., NH₂COPh-), 4-benzoylphen-1-yl, dicyanomethylidenebis(4-phen-1-yloxy) (i.e., —OPhC(CN)₂PhO—), 3-methylphen-1-yl, methylenebis(4-phen-1-yloxy) (i.e., —OPhCH₂PhO—), 2-ethylphen-1-yl, phenylethenyl, 3-formyl-2-thienyl, 2-hexyl-5-furanyl, hexamethylene-1,6-bis(4-phen-1-yloxy) (i.e., —OPh(CH₂)₆PhO-), 4-hydroxymethylphen-1-yl (i.e., 4-HOCH₂Ph-), 4-mercaptomethylphen-1-yl (i.e., 4-HSCH₂Ph-), 4-methylthiophen-1-yl (i.e., 4-CH₃SPh-), 3-methoxyphen-1-yl, 2-methoxycarbonylphen-1-yloxy (e.g., methyl salicyl), 2-nitromethylphen-1-yl (i.e., 2-NO₂CH₂Ph), 3-trimethylsilylphen-1-yl, 4-t-butyldimethylsilylphenl-1-yl, 4-vinylphen-1-yl, vinylidenebis(phenyl), and the like. The term “a C₃- CIo aromatic radical” includes aromatic radicals containing at least three but no more than 10 carbon atoms. The aromatic radical 1-imidazolyl (C₃H₂N₂—) represents a C₃ aromatic radical. The benzyl radical (C₇H₇—) represents a C₇ aromatic radical.

As used herein the term “cycloaliphatic radical” refers to a radical having a valence of at least one, and comprising an array of atoms which is cyclic but which is not aromatic. As defined herein a “cycloaliphatic radical” does not contain an aromatic group. A “cycloaliphatic radical” may comprise one or more noncyclic components. For example, a cyclohexylmethyl group (C₆H₁₁CH₂—) is an cycloaliphatic radical which comprises a cyclohexyl ring (the array of atoms which is cyclic but which is not aromatic) and a methylene group (the noncyclic component). The cycloaliphatic radical may include heteroatoms such as nitrogen, sulfur, selenium, silicon and oxygen, or may be composed exclusively of carbon and hydrogen. For convenience, the term “cycloaliphatic radical” is defined herein to encompass a wide range of functional groups such as alkyl groups, alkenyl groups, alkynyl groups, haloalkyl groups, conjugated dienyl groups, alcohol groups, ether groups, aldehyde groups, ketone groups, carboxylic acid groups, acyl groups (for example carboxylic acid derivatives such as esters and amides), amine groups, nitro groups, and the like. For example, the 4-methylcyclopent-1-yl radical is a C₆ cycloaliphatic radical comprising a methyl group, the methyl group being a functional group which is an alkyl group. Similarly, the 2-nitrocyclobut-1-yl radical is a C₄ cycloaliphatic radical comprising a nitro group, the nitro group being a functional group. A cycloaliphatic radical may comprise one or more halogen atoms which may be the same or different. Halogen atoms include, for example; fluorine, chlorine, bromine, and iodine. Cycloaliphatic radicals comprising one or more halogen atoms include 2-trifluoromethylcyclohex-1-yl, 4-bromodifluoromethylcyclooct-1-yl, 2-chlorodifluoromethylcyclohex-1-yl, hexafluoroisopropylidene-2,2-bis(cyclohex-4-yl) (i.e., —C₆H₁₀C(CF₃)₂C₆H₁₀—), 2-chloromethylcyclohex-1-yl, 3-difluoromethylenecyclohex-1-yl, 4-trichloromethylcyclohex-1-yloxy, 4-bromodichloromethylcyclohex-1-ylthio, 2-bromoethylcyclopent-1-yl, 2-bromopropylcyclohex-1-yloxy (e.g., CH₃CHBrCH₂C₆H₁₀—), and the like. Further examples of cycloaliphatic radicals include 4-allyloxycyclohex-1-yl, 4-aminocyclohex-1-yl (i.e., H₂NC₆H₁₀—), 4-aminocarbonylcyclopent-1-yl (i.e., NH₂COC₅H₈—), 4-acetyloxycyclohex-1-yl, 2,2-dicyanoisopropylidenebis(cyclohex-4-yloxy) (i.e., —OC₆H₁₀C(CN)₂C₆H₁₀O—), 3-methylcyclohex-1-yl, methylenebis(cyclohex-4-yloxy) (i.e., —OC₆H₁₀CH₂C₆H₁₀O—), 1-ethylcyclobut-1-yl, cyclopropylethenyl, 3-formyl-2-terahydrofuranyl, 2-hexyl-5-tetrahydrofuranyl, hexamethylene-1,6-bis(cyclohex-4-yloxy) (i.e., —OC₆H₁₀(CH₂)₆C₆H₁₀O—), 4-hydroxymethylcyclohex-1-yl (i.e., 4-HOCH₂C₆H₁₀—), 4-mercaptomethylcyclohex-1-yl (i.e., 4-HSCH₂C₆H₁₀—), 4-methylthiocyclohex-1-yl (i.e., 4-CH₃SC₆H₁₀—), 4-methoxycyclohex-1-yl, 2-methoxycarbonylcyclohex-1-yloxy (2-CH₃OCOC₆H₁₀O—), 4-nitromethylcyclohex-1-yl (i.e., NO₂CH₂C₆H₁₀—), 3-trimethylsilylcyclohex-1-yl, 2-t-butyldimethylsilylcyclopent-1-yl, 4-trimethoxysilylethylcyclohex-1-yl (e.g., (CH₃O)₃SiCH₂CH₂C₆H₁₀—), 4-vinylcyclohexen-1-yl, vinylidenebis(cyclohexyl), and the like. The term “a C₃-C₁₀ cycloaliphatic radical” includes cycloaliphatic radicals containing at least three but no more than 10 carbon atoms. The cycloaliphatic radical 2-tetrahydrofuranyl (C₄H₇O—) represents a C₄ cycloaliphatic radical. The cyclohexylmethyl radical (C₆H₁₁CH₂—) represents a C₇ cycloaliphatic radical.

As used herein the term “aliphatic radical” refers to an organic radical having a valence of at least one consisting of a linear or branched array of atoms which is not cyclic. Aliphatic radicals are defined to comprise at least one carbon atom. The array of atoms comprising the aliphatic radical may include heteroatoms such as nitrogen, sulfur, silicon, selenium and oxygen or may be composed exclusively of carbon and hydrogen. For convenience, the term “aliphatic radical” is defined herein to encompass, as part of the “linear or branched array of atoms which is not cyclic” a wide range of functional groups such as alkyl groups, alkenyl groups, alkynyl groups, haloalkyl group, conjugated dienyl groups, alcohol groups, ether groups, aldehyde groups, ketone groups, carboxylic acid groups, acyl groups (for example carboxylic acid derivatives such as esters and amides), amine groups, nitro groups, and the like. For example, the 4-methylpent-1-yl radical is a C₆ aliphatic radical comprising a methyl group, the methyl group being a functional group which is an alkyl group. Similarly, the 4-nitrobut-1-yl group is a C₄ aliphatic radical comprising a nitro group, the nitro group being a functional group. An aliphatic radical may be a haloalkyl group which comprises one or more halogen atoms which may be the same or different. Halogen atoms include, for example; fluorine, chlorine, bromine, and iodine. Aliphatic radicals comprising one or more halogen atoms include the alkyl halides trifluoromethyl, bromodifluoromethyl, chlorodifluoromethyl, hexafluoroisopropylidene, chloromethyl, difluorovinylidene, trichloromethyl, bromodichloromethyl, bromoethyl, 2-bromotrimethylene (e.g., —CH₂CHBrCH₂—), and the like. Further examples of aliphatic radicals include allyl, aminocarbonyl (i.e., —CONH₂), carbonyl, 2,2-dicyanoisopropylidene (i.e., —CH₂C(CN)₂CH₂—), methyl (i.e., —CH₃), methylene (i.e., —CH₂—), ethyl, ethylene, formyl (i.e., —CHO), hexyl, hexamethylene, hydroxymethyl (i.e., —CH₂OH), mercaptomethyl (i.e., —CH₂SH), methylthio (i.e., —SCH₃), methylthiomethyl (i.e., —CH₂SCH₃), methoxy, methoxycarbonyl (i.e., CH₃OCO—), nitromethyl (i.e., —CH₂NO₂), thiocarbonyl, trimethylsilyl (i.e., (CH₃)₃Si—), t-butyldimethylsilyl, 3-trimethyoxysilypropyl (i.e., (CH₃O)₃SiCH₂CH₂CH₂—), vinyl, vinylidene, and the like. By way of further example, a C₁-C₁₀ aliphatic radical contains at least one but no more than 10 carbon atoms. A methyl group (ie., CH₃—) is an example of a C₁ aliphatic radical. A decyl group (i.e., CH₃(CH2)₉-) is an example of a C₁₀ aliphatic radical.

As used herein, the term “electromagnetic radiation” means electromagnetic radiation having wavelength in the range from about 200 nm to about 2500 nm.

As noted, the present invention provides a composition comprising at least one metal complex, such that the metal complex comprises at least one metal atom, at least one first organic ligand comprising at least one triarylamine group, at least one second ligand comprising at least one acidic group, and at least one thiocyanate or isothiocyanate ligand.

In one embodiment of the present invention the metal atom of the metal complex is a metal cation capable of forming four coordinate complexes and/or six-coordinate complexes, said cation being chosen from cations of iron, cations of ruthenium, cations of osmium, cations of technetium, cations of rhodium, and mixtures of two or more of the foregoing cations.

The first organic ligand comprises at least one triarylamine group. In one embodiment, the first organic ligand is chosen from the group consisting of organic ligands having structures I, II, III, IV, V, VI, VII and VIII; 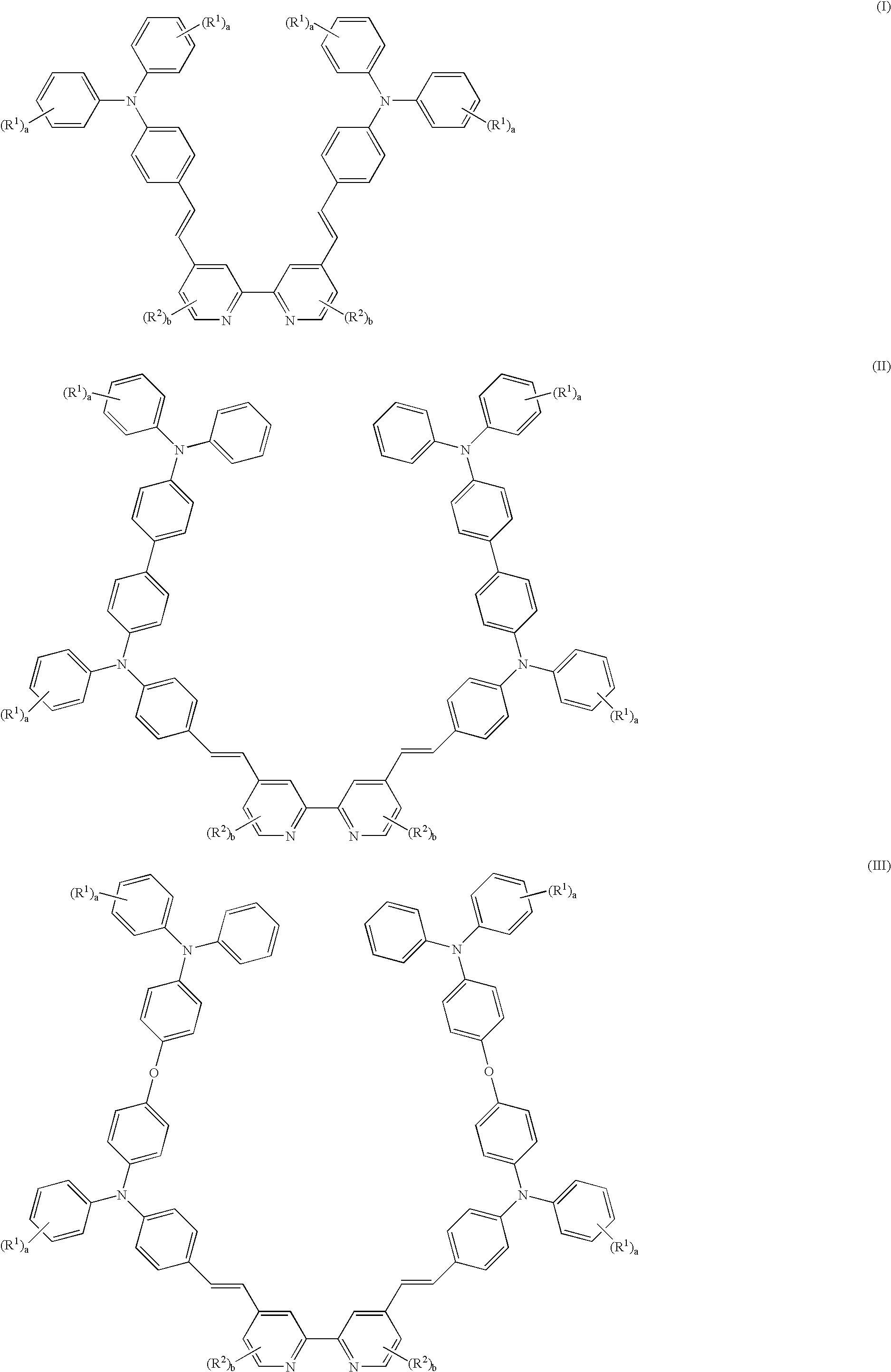 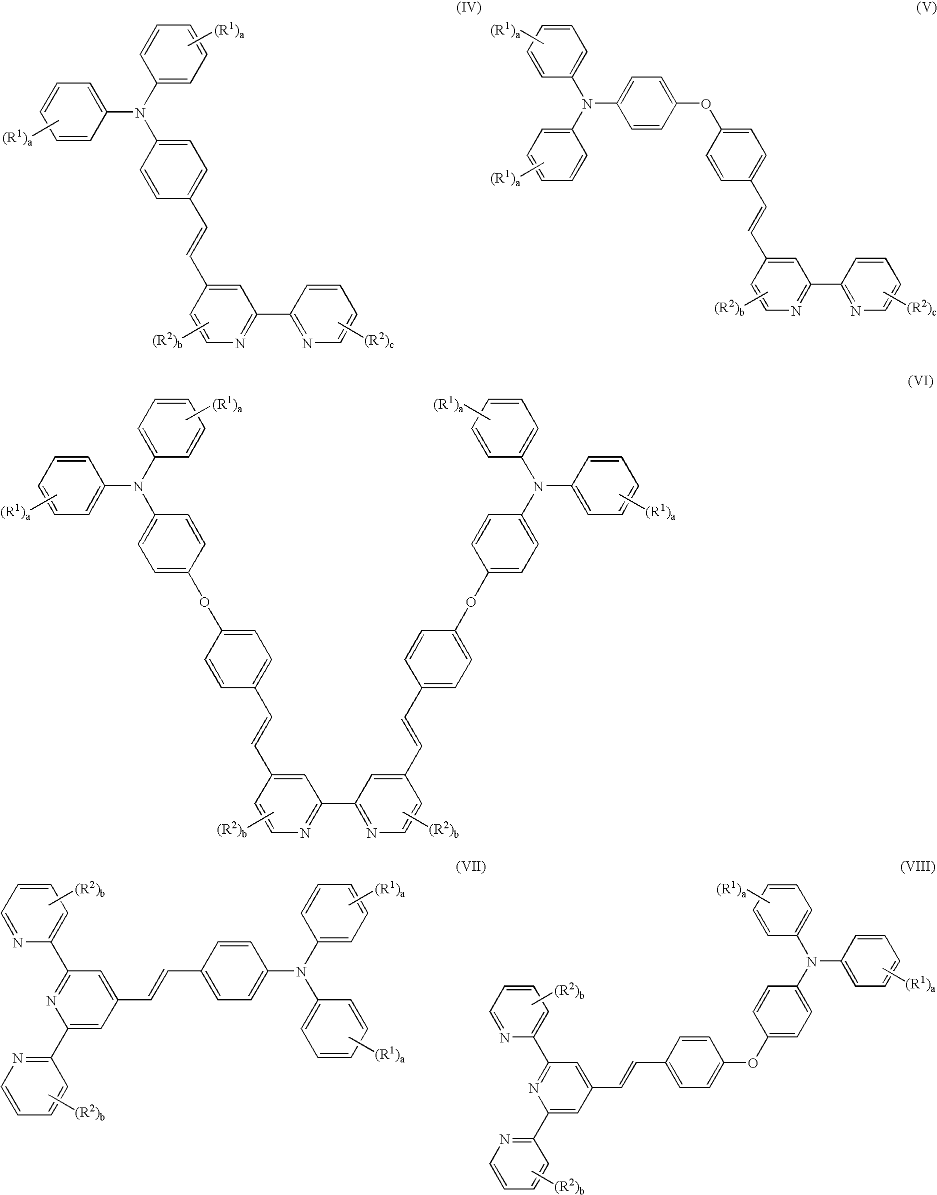
wherein a is independently at each occurence an integer from 0 to 5, b is independently at each occurence an integer from 0 to 3, and c is independently at each occurence an integer from 0 to 4; and R¹ and R² are independently at each occurence a C₁-C₃₀ aliphatic radical, a C₃-C₃₀ aromatic radical, a C₃-C₃₀ cycloaliphatic radical, a halogen atom, a hydroxyl group (OH), a nitro group, or a cyano group. In one embodiment, at least one of R¹ or R² is a carboxy group, said carboxy group representing a C₁ aliphatic radical. In another emboiment, at least one of R¹ or R² is a C₁-C₃₀ alkoxy group, said C₁-C₃₀ alkoxy group representing a C₁-C₃₀ aliphatic radical. In yet another embodiment, at least one of of R¹ or R² is a C₃-C₃₀ aryloxy group, said C₃-C₃₀ aryloxy group representing a C₃-C₃₀ aromatic radical. In yet another embodiment, at least one of R¹ or R² is a triarylamine group, said triaryl amine group representing an aromatic radical.

In one embodiment of the present invention, the subscripts “a”, “b” and “c” of structures I, II, III, IV, V, VI, VII and VIII are equal to zero. In another embodiment of the present invention, subscript “a” of structures I, II, II, IV, V, VI, VII and VIII is equal to one. In yet another embodiment, the subscripts “b” and “c” of structures I, II, III, IV, V, VI, VII and VIII are equal to zero. In yet another embodiment, subscript “a” of structures I, II, III, IV, V, VI, VII and VIII is equal to zero and subscripts b and c are equal to one.

Thus, by way of example, in one embodiment of the present invention, the first ligand has structure IX. Structure IX falls within generic formula I and represents the case wherein the integers “a” and “b” in structure I are equal to zero.

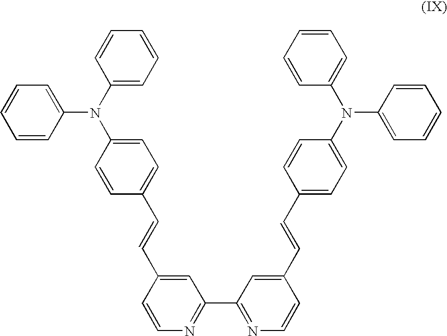

In another embodiment, the first ligand has structure X. Structure X falls within generic formula VII and represents the case wherein the integers “a” and “b” in structure VII are equal to zero. 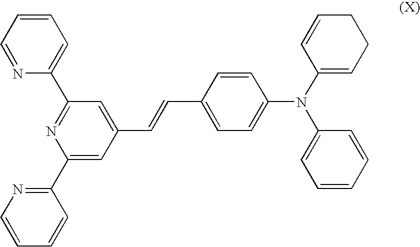
Some other illustrative examples of first ligand species include, but are not limited to structures XI, XII, XIII, XIV, XV, and XVI,

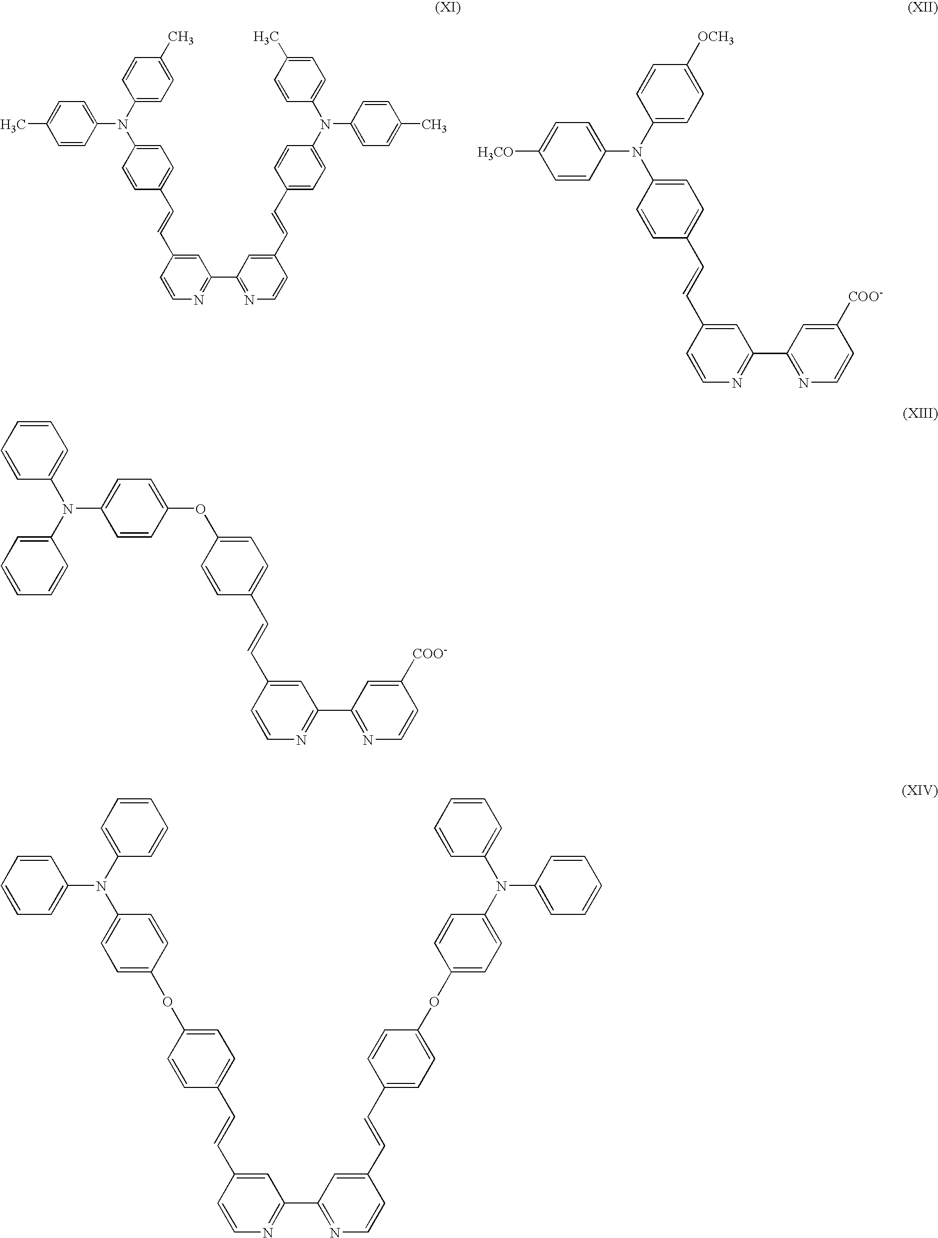

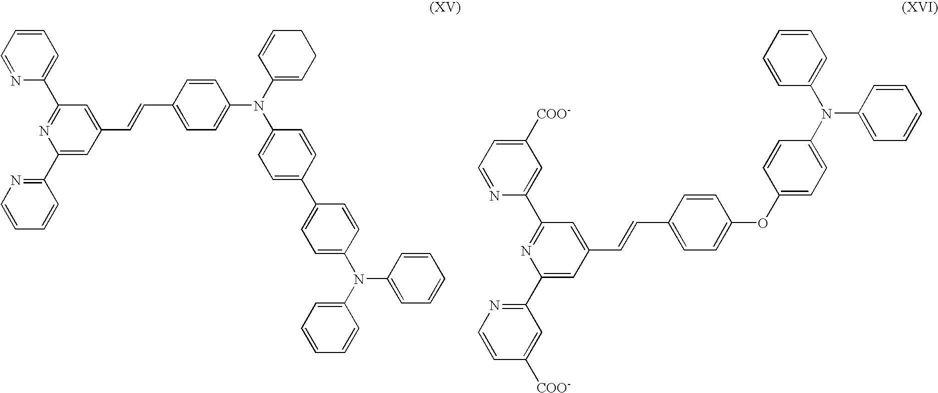

Although not wishing to be bound by any theory, it is believed that the triarylamine groups present in the first ligand improve the molar absorptivity of the dye. It is further believed that the presence of features in the first ligand which promote extended conjugation between the triarylamine moiety and other parts of the dye contributes to the enhanced molar absorptivity of the dye. For example, in structure X the triarylamine moiety is linked via a two carbon unsaturated ethenyl group (—CH═CH—) to the terpyridine portion of the dye thereby promoting extended conjugation between the triarylamine moiety and the rest of the molecule. In certain applications such as in dye-sensitized solar cells, the triarylamine groups may enhance wetting of a nonpolar electrolyte such as solid-state triarylamine hole transport compounds in contact with the dye. Improved wetting or improved interfacial interaction between the dye and the hole transporter may result in increased open circuit voltage across the cell by reducing the unproductive back reactions or recombination reactions. Moreover, improved contact between the electrolyte and the dye may also enhance charge transfer at the interface as well as regeneration of the dye, thereby resulting in an improved overall quantum efficiency of the dye-sensitized solar cell.

In another embodiment, the first organic ligand may comprise one or more electron donating groups, for example, alkoxy groups or aryloxy groups. In one embodiment one or more of the aryl radicals constituting the triarylamine group is comprises one or more alkoxy groups, aryloxy groups, or combinations thereof. In yet another embodiment, the first ligand comprises one or more electron withdrawing groups. See for example structures XII and XIII wherein the bipyridyl moiety of the first ligand is substituted by a carboxylate group (CO₂⁻), an electron-withdrawing group. Other electron withdrawing groups which may be present in the first ligand include halogen atoms, cyano groups, ester groups, nitro groups, and the like. In various embodiments of the present invention, electron-donating and electron-withdrawing groups may facilitate transfer of electrons from peripheral triarylamine groups to the metal core via a “push-pull mechanism”, and thereby inhibit unproductive recombination.

The second organic ligand comprises at least one acidic group. Typically, the second ligand comprises at least two acidic groups. In dye sensitized solar cell applications, for example, the acidic groups serve to anchor the metal complex to the surface of a semiconductor layer. It is believed that a close interaction of this type results in improvement of the adsorbing efficiency of the metal complex dye. Suitable examples of acidic groups include but are not limited to carboxylic acid groups, sulfonic acid groups, phosphonic acid groups, sulfinic acid groups, boronic acid groups, their salts and mixtures thereof. The preferred acidic groups for dyes used in solar cells are carboxylic acid groups or phosphonic acid groups, because they are thought to interact strongly with the surface hydroxyl groups of the semiconductor surface. It should be noted that the term acidic group encompasses both protonated and deprotonated forms of the acidic group. For example, when the acidic group is described as a “carboxylic acid group”, it is to be understood that both the protonated form of the carboxylic acid (CO₂H) and deprotonated form of the carboxylic acid (CO₂⁻) are included within the meaning of the term “carboxylic acid group”. The deprotonated form of the “carboxylic acid group” at times is referred to herein as a “carboxylate group” (CO₂⁻).

In one embodiment of the present invention, the second ligand has structure XVII 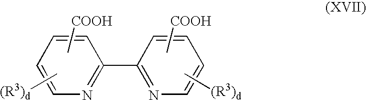
wherein “d” is independently at each occurence an integer from 0 to 3; and R³ is independently at each occurrence a halogen atom, a nitro group, a cyano group, a carboxy group, a hydroxyl group, a C₁-C₃₀ aliphatic radical, a C₃-C₃₀ aromatic radical, or a C₃-C₃₀ cycloaliphatic radical.

Some illustrative examples of second ligands falling within generic structure XVII include, but are not limited to, structures XVIII, XIX and XX. In order to avoid confusion, it is noted here that in structures XIX and XX at least one of the substituents R³ is a carboxy group. It is further noted that a carboxy group (CO₂H) is defined herein as a C₁ aliphatic radical.

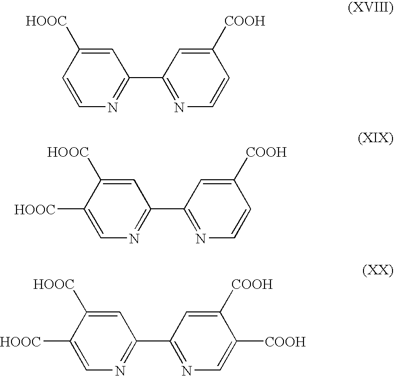

In one embodiment of the present invention, the second organic ligand is 2,2′-bipyridine-4,4′-dicarboxylic acid having structure XVIII. Structure XVIII exemplifies structure XVII where c and d are equal to 0 and the carboxylic acid groups are located at the 4- and 4′-positions of the 2,2′-bipyridine nucleus. The presence of the anchoring carboxylic acid groups at the 4- and 4′-positions of the 2,2′-bipyridyl nucleus of the second ligand is believed to enable the metal complex dye composition to self-organize on the semiconductor surface and to promote electronic coupling of the donor levels of the dye with the acceptor levels of the semiconductor.

The metal complex also comprises at least one thiocyanate (⁻S—CN) or isothiocyanate (⁻N═C═S) ligand. The thiocyanate or isothiocyanate ligands are believed to stabilize the metal complex dye and allow a measure of control of the spectral response (e.g. λ-max and absorptivity) of the metal complex dye. In one embodiment of the present invention, the metal complex dye may further include at least one additional ligand comprising an anion chosen from halogen atoms, hydroxyl groups, cyano groups (⁻CN), cyanate groups (⁻O—CN), isocyanate groups (⁻N═C═O), selenocyanate groups (⁻Se—CN), and isoselenocyanate groups (⁻N═C═Se).

In one embodiment of the present invention, the metal complex has structure XXI. 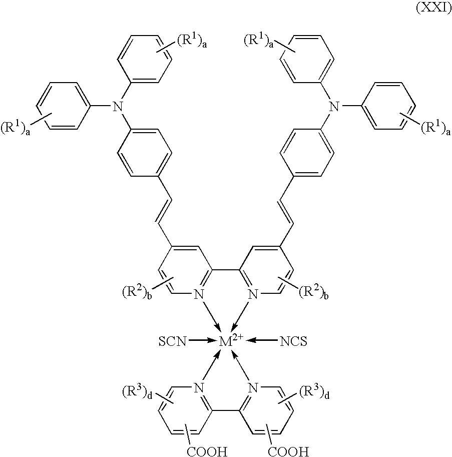
wherein “a” is independently at each occurrence an integer from 0 to 5, “b” is independently at each occurrence an integer from 0 to 3, and “c” and “d” are independently at each occurrence an integers from 0 to 4; R¹ and R² are independently at each occurence a C₁-C₃₀ aliphatic radical, a C₃-C₃₀ aromatic radical, a C₃-C₃₀ cycloaliphatic radical, a halogen atom, a nitro group, a cyano group, a carboxy group, a hydroxyl group, a C₁-C₃₀ alkoxy group, a C₁-C₃₀ aryloxy group, or a triarylamine group; and R³ is independently at each occurrence a halogen atom, a nitro group, a cyano group, a carboxy group, a hydroxyl group, a C₁-C₃₀ aliphatic radical, a C₃-C₃₀ aromatic radical, or a C₃-C₃₀ cycloaliphatic radical. In stucture XXI, the ligands designated “SCN→” and “←NCS” may both be thicyanate ligands or isothiocyante ligands, or one may be a thocyante ligand and the other an isothiocyante ligand.

In another embodiment of the present invention, the metal complex comprises a ruthenium cation, a first organic ligand having structure IX, a second organic ligand having structure XVIII, and two thiocyanate or isothiocyanate ligands or a mixture thereof. In a further embodiment of the present invention, the metal complex has structure XXII. Structure XXII falls within generic structure XXI wherein the integers “a”, “b” and “d” of structure XXI are equal to zero and the carboxylic acid groups are located at the 4- and 4′-positions of the 2,2′-bipyridine nucleus of the second organic ligand.

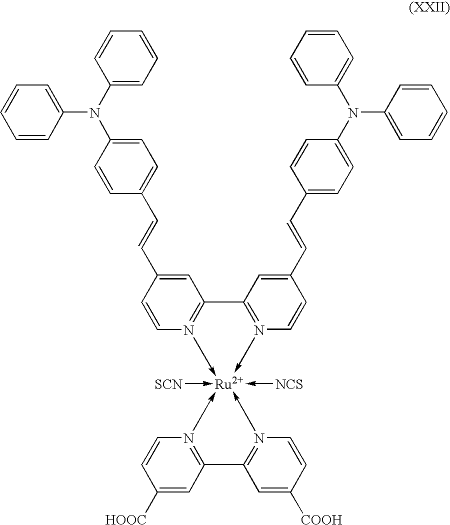

Various known methods may be used to prepare the metal complex dye compositions of the present invention once the requisite ligands have been synthesized. Thus, in one aspect, the present invention provides a method for the preparation of the one or more of the ligands used in the preparation of the metal complex dye compositions. In one embodiment, the first organic ligand, for example structure IX, is assembled from a halogenated 4,4′-dimethyl-2,2′-bipyridine and a triphenylamine aldehyde via Wittig reaction to produce the first ligand featuring a conjugated vinylene spacer between the bipyridyl moiety and the triarylamine moiety via Wittig reaction. Once in hand, this first ligand is reacted with 0.5 equivalents of a metal chloride complex in a solvent, followed by equivalent amount of a second ligand, for example a ligand having structure XVIII. The resultant complex is further reacted with a third anionic ligand. In one embodiment the third ligand is thiocyanate. Typically a third ligand may be introduced into the metal complex by reacting a metal chloride complex in sequence with a first ligand, a second ligand, and lastly with an excess of a third ligand. The reaction product comprising the metal complex dye may be purified by conventional techniques such as crystallization, trituration, and/or chromatography.

The compositions of the present invention are useful as photosensitizers for applications in optoelectronic devices, optical sensors, devices for hydrogen preparation by water splitting, and as absorptive contrast agents. In one embodiment, the compositions of the present invention are comprised within the dye component of a dye-sensitized electrode. In a further embodiment, the compositions of the present invention are comprised within the dye component of a dye-sensitized electrode present in a dye-sensitized solar cell.

Thus, in one embodiment, the present invention provides a dye-sensitized electrode comprising a substrate having an electrically conductive surface, an electron transporting layer that is disposed on the electrically conductive surface, and a composition comprising at least one metal complex disposed on the electron transporting layer. The metal complex comprises at least one metal atom, at least one first organic ligand comprising at least one triarylamine group, at least one second ligand comprising at least one acidic group, and at least one thiocyanate or isothiocyanate ligand.

In one embodiment, the substrate of the dye-sensitized electrode comprises at least one glass film. In an alternate embodiment the substrate comprises at least one polymeric material. Examples of suitable polymeric materials include but are not limited to polyacrylates, polycarbonates, polyesters, polysulfones, polyetherimides, silicones, epoxy resins, and silicone-functionalized epoxy resins. The substrate is selected so that it is substantially transparent, that is, a test sample of the substrate material having a thickness of about 0.5 micrometer allows approximately 80 percent of incident electromagnetic radiation having wavelength in the range from about 290 nm to about 1200 nm at an incident angle less than about 10 degrees to be transmitted through the sample.

At least one surface of the substrate is coated with a substantially transparent, electrically conductive material. Suitable materials that can be for coating are substantially transparent conductive oxides, such as indium tin oxide (ITO), tin oxide, indium oxide, zinc oxide, antimony oxide, and mixtures thereof. A substantially transparent layer, a thin film, or a mesh structure of metal such as silver, gold, platinum, titanium, aluminum, copper, steel, or nickel may be also suitable.

The dye-sensitized electrode further comprises an electron-transporting layer disposed in electrical contact with the electrically conductive material coated on the substrate. The electron-transporting layer facilitates transfer of charge across the cell by transferring the electron ejected from the metal complex to the electrode. It is thus desirable for the electron transporting layer to have a lowest unoccupied molecular orbital (LUMO) energy level or conduction band edge that closely matches the LUMO of the metal complex to facilitate the transport of electrons between the metal complex and said electron transporting layer.

Examples of suitable materials for electron transporting layer include, but is are not limited to, metal oxide semiconductors; tris-8-hydroxyquinolato aluminum (AIQ₃); cyano-polyphenylene vinylene (CN-PPV); and oligomers or polymers comprising electron deficient heterocyclic moieties, such as 2,5-diaryloxadiazoles, diaryl trazoles, triazines, pyridines, quinolines, benzoxazoles, benzthiazoles, or the like. Other exemplary electron transporters are particularly functionalized fullerenes (e.g., 6,6-phenyl-C61-butyl acid-methylester), difluorovinyl-(hetero)arylenes, 3-(1,1-difluoro-alkyl)thiophene group, pentacene, poly(3-hexylthiophene), α,ω-substituted sexithiophenes, n-decapentafluoroheptyl-methylnaphthalene-1,4,5,8-tetracarboxylic diimide, dihexyl-quinquethiophene, poly(3-hexylthiophene), poly(3-alkylthiophene), di-hexyl-hexathiophene, dihexyl-anthradithiophene, phthalocyanine, C60 fullerene, or the like, or a combination comprising at least one of the foregoing electron transporters.

In one embodiment, a metal-oxide semiconductor is used as an electron-transporting layer. Suitable metal oxide semiconductors are oxides of the transition metals and oxides of the elements of Group III, IV, V, and VI of the Periodic Table. Oxides of titanium, zirconium, hafnium, strontium, zinc, indium, yttrium, lanthanum, vanadium, niobium, tantalum, chromium, molybdenum, tungsten, iron, nickel, silver or mixed oxides of these metals may be employed. Other suitable oxides include those having a perovskite structure such as SrTiO₃ or CaTiO₃. The semiconductor layer is coated by adsorption of the composition comprising the metal complex on the surface thereof. As noted, the metal complex is thought to interact strongly with the surface of the semiconductor layer via the acidic groups present in the composition. In another embodiment titanium dioxide (TiO₂) is used as an electron-transporting layer.

In a further embodiment, the present invention provides a dye sensitized electrode comprising a substrate having an electrically conductive surface, a titanium dioxide (TiO₂) layer that is disposed on the electrically conductive surface, and a composition comprising at least one metal complex disposed on the said TiO₂ layer. The metal complex comprises a ruthenium cation, a first organic ligand having structure IX, a second organic ligand having structure XVIII, and two thiocyanate or isothiocyanate ligands.

In one embodiment, the present invention provides a solar cell comprising a dye sensitized electrode comprising a substrate having an electrically conductive surface, an electron transporting layer that is disposed on the electrically conductive surface, and a composition comprising at least one metal complex disposed on the electron transporting layer; a counter electrode; and a hole transporting layer in contact with the dye-sensitized electrode and the counter electrode. The metal complex comprises at least one metal atom, at least one first organic ligand comprising at least one triarylamine group, at least one second ligand comprising at least one acidic group, and at least one thiocyanate or isothiocyanate ligand.

Any electrically conductive material may be used as the counter electrode. Illustrative examples of suitable counter electrodes are a platinum electrode, a rhodium electrode, a ruthenium electrode or a carbon electrode.

The hole-transporting layer facilitates transfer of charge across the cell by transferring the holes from the metal complex to the electrode. Thus, it is also desirable for the hole-transporting layer to have a highest occupied molecular orbital (HOMO) energy level that closely matches the HOMO of the metal complex to facilitate the transport of holes between the metal complex and the hole-transporting layer.

Examples of suitable materials for hole transporting layer includes, but are not limited to, hydrazone compounds, styryl compounds, diamine compounds, aromatic tertiary amine compounds, butadiene compounds, indole compounds, carbazole derivatives, triazole derivatives, imidazole derivatives, oxadiazole derivatives having an amino group, or the like, or a combination comprising at least one of the foregoing materials. Yet other examples of suitable hole transporters are triphenylmethane, bis(4-diethylamine-2-methylphenyl) phenylmethane, stylbene, hydrozone; aromatic amines comprising tritolylamine; arylamine; enamine phenanthrene diamine; N,N′-bis-(3,4-dimethylphenyl)-4-biphenyl amine; N,N′-bis-(4-methylphenyl)-N,N′-bis(4-ethylphenyl)-1,1′-3,3′-dimethylbiphenyl)-4,4′-diamine; 4-4′-bis(diethylamino)-2,2′-dimethyltriphenylmethane; N,N′-diphenyl-N,N′-bis(3-methylphenyl)-[1,1′-biphenyl]-4,4′-diamine; N,N′-diphenyl-N,N′-bis(4-methylphenyl)-1,1′-biphenyl-4,4′-diamine; N,N′-diphenyl-N,N′-bis(alkylphenyl)-1,1′-biphenyl-4,4′-diamine; and N,N′-diphenyl-N,N′-bis(chlorophenyl)-1,1′-biphenyl-4,4′-diamine; 1,1-bis(4-di-p-tolylaminophenyl)cyclohexane; 1,1-bis(4-di-p-tolylaminophenyl)-4-phenylcyclohexane; 4,4′-bis(diphenylamino)quadriphenyl; bis(4-dimethylamino-2-methylphenyl)-phenylmethane; N,N,N-Tri(p-tolyl)amine; 4-(di-p-tolylamino)-4′-[4(di-p-tolylamino)-styryl]stilbene; N,N,N′,N′-tetra-p-tolyl-4-4′-diaminobiphenyl; N,N,N′,N′-tetraphenyl-4,4′-diaminobiphenyl; N,N,N′,N′-tetra-1-naphthyl-4,4′-diaminobiphenyl; N,N,N′,N′-tetra-2-naphthyl-4,4′-diaminobiphenyl; N-phenylcarbazole; 4,4′-bis[N-(1-naphthyl)-N-phenylamino]biphenyl; 4,4′-bis[N-(1-naphthyl)-N-(2-naphthyl)amino]biphenyl; 4,4″-bis[N-(1-naphthyl)-N-phenylaamino]p-terphenyl; 4,4′-bis[N-(2-naphthyl)-N-phenylamino]biphenyl; 4,4′-bis[N-(3-acenaphthenyl)-N-phenylamino]biphenyl; 1,5-bis[N-(1-naphthyl)-N-phenylamino]naphthalene; 4,4′-bis[N-(9-anthryl)-N-phenylamino]biphenyl; 4,4″-bis[N-(1-anthryl)-N-phenylamino]-p-terphenyl; 4,4′-bis[N-(2-phenanthryl)-N-phenylamino]biphenyl; 4,4′-bis[N-(8-fluoranthenyl)-N-phenylamino]biphenyl; 4,4′-bis[N-(2-pyrenyl)-N-phenylamino]biphenyl; 4,4′-bis[N-(2-naphthacenyl)-N-phenylamino]biphenyl; 4,4′-bis[N-(2-perylenyl)-N-phenylamino]biphenyl; 4,4′-bis[N-(1-coronenyl)-N-phenylamino]biphenyl; 2,6-bis(di-p-tolylamino)naphthalene; 2,6-bis[di-(1-naphthyl)amino]naphthalene; 2,6-bis[N-(1-naphthyl)-N-(2-naphthyl)amino]naphthalene; N,N,N′,N′-tetra(2-naphthyl)-4,4″-diamino-p-terphenyl; 4,4′-bis{N-phenyl-N-[4-(1-naphthyl)-phenyl]amino}biphenyl; 4,4′-bis[N-phenyl-N-(2-pyrenyl)amino]biphenyl; 2,6-bis[N,N-di(2-naphthyl)amine]fluorine; 1,5-bis[N-(1-naphthyl)-N-phenylamino]naphthalene; or the like, or a combination comprising at least one of the foregoing hole transporters.

The hole-transporting layer may also comprise intrinsically conducting polymers. Examples of suitable intrinsically conducting polymers are poly(acetylene) and its derivatives; poly(thiophenes) and its derivatives; poly(3,4-ethylenedioxythiophene) and poly(3,4-ethylenedithiathiophene) and their derivatives; poly(isathianaphthene), poly(pyridothiophene), poly(pyrizinothiophene), and their derivatives; poly(pyrrole) and its derivatives; poly(3,4-ethylenedioxypyrrole) and its derivatives; poly(aniline) and its derivatives; poly(phenylenevinylene) and its derivatives; poly(p-phenylene) and its derivatives; poly(thionapthene), poly(benzofuran), and poly(indole) and their derivatives; poly(dibenzothiophene), poly(dibenzofuran), poly(carbazole) and their derivatives; poly(bithiophene), poly(bifuran), poly(bipyrrole), and their derivatives; poly(thienothiophene), poly(thienofuran), poly(thienopyrrole), poly(furanylpyrrole), poly(furanylfuran), poly(pyrolylpyrrole), and their derivatives; poly(terthiophene), poly(terfuran), poly(terpyrrole), and their derivatives; poly(dithienothiophene), poly(difuranylthiophene), poly(dipyrrolylthiophene), poly(dithienofuran), poly(dipyrrolylfuran), poly(dipyrrolylpyrrole) and their derivatives; poly(phenyl acetylene) and its derivatives; poly(biindole) and derivatives; poly(dithienovinylene), poly(difuranylvinylene), poly(dipyrrolylvinylene) and their derivatives; poly(1,2-trans(3,4-ethylenedioxythienyl)vinylene), poly(1,2-trans(3,4-ethylenedioxyfuranyl)vinylene), poly(1,2-trans(3,4-ethylenedioxypyrrolyl)vinylene), and their derivatives; poly(bis-thienylarylenes) and poly(bis-pyrrolylarylenes) and their derivatives; poly(dithienylcyclopentenone); poly(quinoline); poly(thiazole); poly(fluorene); poly(azulene); or the like, or a combination comprising at least one of the foregoing intrinsically conducting polymers.

The hole-transporting layer may be liquid or solid. In the case of a liquid hole transporting layer an ionic liquid or an electrolyte may be used. Suitable examples of ionic liquids that may used as the hole transporter are methylpropylimidazolium triaflate, methylpropylimidazolium bistriflimide, methylpropylimidazolium nanoaflate, methylpropylimidazolium ethersulfonate, methylpropylimidazolium iodide methylpropylimidazolium triiodide, methylpropylimidazolium halides, metal complex cations with phosphonium anion, or the like, or a combination comprising at least one of the foregoing hole transporters.

In one embodiment a redox electrolyte is used as a hole-transporting layer. The redox electrolyte can be, for example, a I⁻/I₃⁻ system, a Br⁻/Br₃⁻ system, or a quinone/hydroquinone system. The electrolyte can be liquid or solid. The solid electrolyte can be obtained by dispersing the electrolyte in a polymeric material. In the case of a liquid electrolyte, an electrochemical inert solvent such as acetonitrile, propylene carbonate or ethylene carbonate may be used.

The dye-sensitized electrode, the counter electrode and the hole-transporting layer may be arranged in a case or encapsulated within a resin in a way such that the dye-sensitized electrode is capable of being irradiated with electromagnetic radiation. When the dye-sensitized electrode is irradiated, an electric current is generated as a result of the electrical potential difference created during irradiation.

In a further embodiment, the present invention provides a solar cell comprising a dye sensitized electrode comprising a substrate having an electrically conductive surface, a titanium dioxide (TiO₂) layer that is disposed on the electrically conductive surface, and a composition comprising at least one metal complex disposed on the TiO₂ layer; a counter electrode; and a hole transporting layer in contact with the dye-sensitized electrode and the counter electrode. The said metal complex comprises a ruthenium cation, a first organic ligand having structure IX, a second organic ligand having structure XVIII, and two thiocyanate or isothiocyanate ligands.

Without further elaboration, it is believed that one skilled in the art can, using the description herein, utilize the present invention to its fullest extent. The following examples are included to provide additional guidance to those skilled in the art in practicing the claimed invention. The examples provided are merely representative of the work that contributes to the teaching of the present application. Accordingly, these examples are not intended to limit the invention, as defined in the appended claims, in any manner.

### EXAMPLES

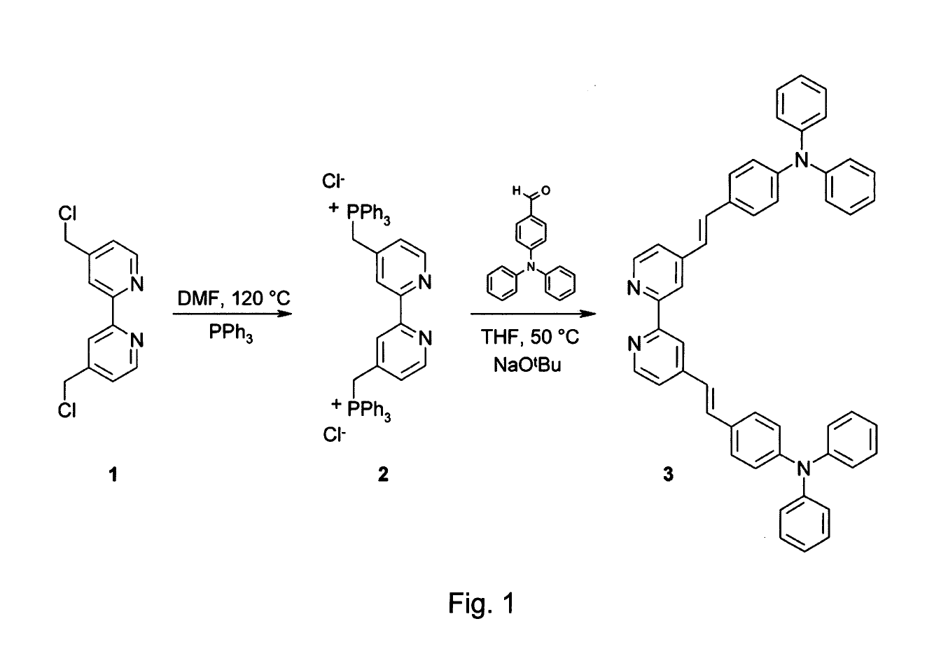

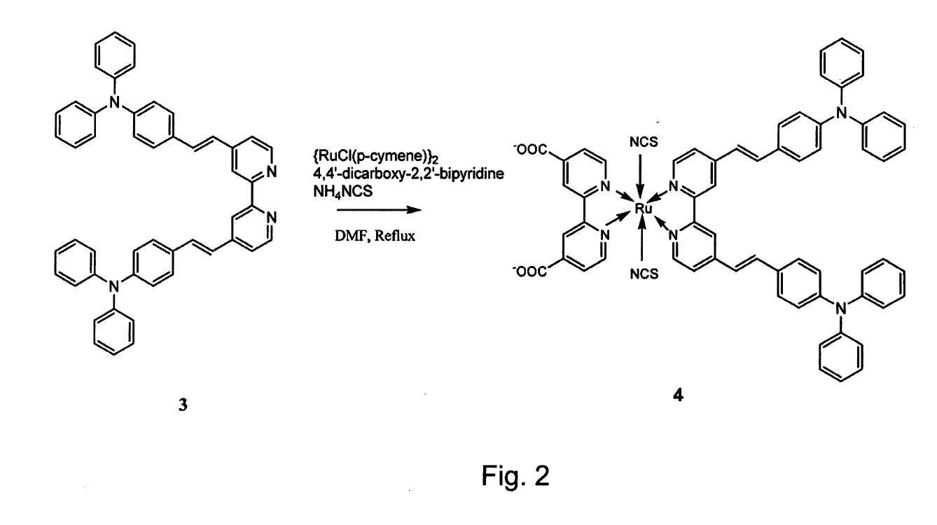

In the following examples, reaction products were analyzed using ¹H NMR Spectroscopy, mass spectrometry and UV-VIS spectrometry. FIGS. 1 and 2 illustrate the reaction scheme for Examples 1 and 2.

### Example 1

Synthesis of 4,4′-bis[4-(diphenylamino)styryl]-2,2′-bipyridine (bpy(TPA)₂, 3): Under an argon atmosphere 4.5 g (5.8 mmol) of bisphosphonium salt 2 (FIG. 1) and 3.17 g (11.6 mmol) of 4-diphenylaminobenzaldehyde were dissolved in 50 ml of dry tetrahydrofuran (THF) and heated to 50° C. A suspension of 2.23 g (23.2 mmol) of NaOtBu in THF was slowly added to the stirred reaction mixture via a dropping funnel followed by stirring at 50° C. for 4 h. After cooling to room temperature the reaction mixture was neutralized with acetic acid (10%) and extracted with CH₂Cl₂. The combined organic fractions were washed with H₂O (2×) and with an aqueous solution of NaOAc (1×). After drying over Na₂SO₄ and evaporation of the solvent, the residue was purified via column chromatography (cyclohexane:EtOAc=5:1) yielding ligand IX, designated structure 3 in FIG. 1, (2 g) as a yellow powder. (Yield=50%). ¹H-NMR (CDCl₃), δ (ppm): 6.95-7.44 (m, 17H), 8.49 (s, 1H, bpy), 8.62 (d, 1H, bpy). FT-IR (KBr), ν (cm⁻¹): 3027, 1583, 1492, 1376, 1330, 1282, 1176, 968, 835, 753, 685. Mass spectrometry: m/z=694 (M⁺). UV-Vis (CHCl₃): λₘₐₓ₁=298 nm, λₘₐₓ₂=398 nm.

### Example 2

Synthesis of Ru(bpyCOOH₂)(bpyTPA₂)(NCS)₂ XXII Dichloro(p-cymene)Ru(II) dimer (0.23 g, 0.375 mmol) was charged to an argon flushed three-neck flask and dissolved in dry dimethylformamide (DMF, 35 ml). Ligand IX prepared in Example 1, bpy(TPA)₂ (0.52 g, 0.75 mmol), was added, the solution was stirred at 100° C. until the starting Ru(II) compound had been fully consumed as judged by thin layer chromatography (TLC). The second ligand, 4,4′-dicarboxy-2,2′-bipyridine (0.183 g, 0.75 mmol) was then added to the above solution and the solution was stirred at 150° C. for 5 h. Subsequently, ammonium thiocyanate (NH₄SCN, 1.43 g, 18.75 mmol) was added and the reaction mixture was stirred at 150° C. for an additional 4-5 hours, DMF was then vacuum-distilled from the reaction flask. The residue was dissolved in THF/methanol and a black solid precipitated after addition of diethylether. The precipitate was collected and washed with diethylether to yield the reddish-brown raw product. Reprecipitation from THF into diethylether yielded 0.3 g of metal complex XXII (shown as structure 4 in FIG. 2) as black powder (Yield: 34%). FT-IR (KBr), ν (cm⁻¹): 3429, 3057, 3030, 2920, 2096, 1724, 1585, 1507, 1491, 1426, 1384, 1314, 1281, 1175, 1019, 962, 753, 695. UV-Vis (DMF): λₘₐₓ₁=305 nm, λₘₐₓ₂=425 nm, λₘₐₓ₃=544 nm.

### Example 3 and Comparative Examples 1-3

Cell performance with complex XXII, XXIII (“N3”), XXIV (“N719”), and XXV (“Z907”). In the following Examples and Comparative Examples, the dyes of the present invention as exemplified by complex XXII, were evaluated for use in dye sensitized solar cells. Metal complex XXII was compared with three known dye species, complex XXIII (“N3” available from Solaronix, Comparative Example 1), complex XXIV (“N719”, available from Solaronix, Comparative Example 2), and complex XXV (“Z907”, available from Solaronix, Comparative Example 3).

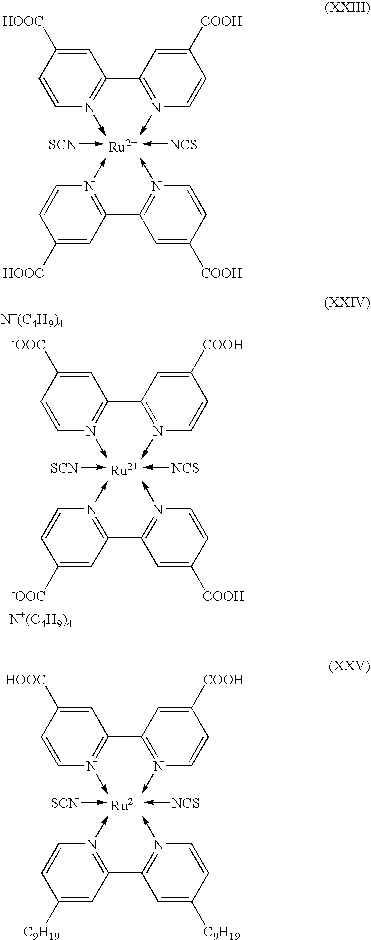

Model cells were prepared as follows: Cells were made with 5 micron and 10 micron TiO₂ films. The titania employed in the films was Fraunhofer titania. Dyeing of the cells was carried out in a Teflon box that held six plates each comprising six 5 mm×50 mm cells; 36 cells in all. Some of the cells were silanized with octyltrimethoxysilane after dyeing to improve cell performance. Conventional electrolyte solutions in acetonitrile (0.5M Pr4NI, 0.1M LiI, 0.45M tBuPyr, 0.05 M I₂) and methylisopropylimidazolium iodide (IL1+Li (0.45M N-MeBzIm, 0.1M LiI, 0.5 M I₂)) were used. Molar extinction coefficients of complex XX and complex XXII were measured at different wavelengths of light. X-ray fluorescence (XRF) was used determine the amount of dye loading on the titania surface. The Ru:Ti intensity ratios were determined to be proportional to dye loading on the titania surface Dye-coated titania films were then assembled into dye sensitized solar cells using standard techniques and tested under 1 sun illumination using one of the above electrolyte solutions.

Solar cell test results are shown in Table 1, Table 2 and Table 3. Table 1 shows molar extinction coefficients of complex XXII when compared to a standard dye complex XXIV in the visible region. Complex XXII shows higher molar extinction coefficients (2-5 times higher) than complex XXIV, complex XXII having a highest molar extinction coefficient of 5.83×10⁴. Complex XXIV is a bistetrabutyl ammonium salt of a standard dye, complex XXIII and does not comprise the triphenylamine groups found in complex XXII. Complex XXII comprises triphenylamine functional groups connected to a bipyridyl ligand via conjugated ethylene linkages. Improved conjugation in the case of complex XXII when compared to complex XXIV is believed to be the source of the improved molar extinction coefficients observed for complex XXII relative to complex XXIV.

TABLE 1
Molar extinction coefficients for XXII and XXIV

| | | | | | | |
|---|---|---|---|---|---|---|
| Dye | λₘₐₓ₁ | ε₁ | λₘₐₓ₂ | ε₂ | λₘₐₓ₃ | ε₃ |

| | | | | | | |
|---|---|---|---|---|---|---|
| XXIV | 309 | 4.64e4 | 378 | 1.15e4 | 514 | 1.17e4 |
| XXII | 307 | 5.83e4 | 423 | 5.45e4 | 526 | 2.45e4 |

Table 2 shows dye loading on the titania surface of the cells for complex XXII relative to a standard dye complex XXIII. Complex XXII exhibited a lower Ru/Ti intensity ratio in XRF measurements. This is taken to mean that the loading of complex XXII on the surface of the titania was lower for complex XXII than for complex XXIII.

TABLE 2
Dye loading by XRF

| Sample Name | Ru/Ti intensity Ratio |
|---|---|
| XXIII from EtOH | 0.0038 ± 0.0001 |
| | (2% RSD) |
| XXII from DMSO | 0.0028 ± 0.0001 |
| | (4% RSD) |

Table 3 shows the solar cell results obtained using dyes XXII and XXV, tested under 1 sun illumination using standard electrolytes. Complex XXII at only 50-60% of the loading of complex XXV showed cell performance equivalent to that exhibited by cells incorporating complex XXV at higher loading, producing the same or better currents and power efficiencies. This may reflect the greater molar absorptivity of complex XXII.

TABLE 3
Cell Performance

| Dye | electrolyte | silanization | Voc | Jsc | FF | Eff |
|---|---|---|---|---|---|---|
| XXV | Std | C₈H₁₇Si(OCH₃)₃ | | | | |
| | Std | none | 669 | 11.3 | 0.62 | 4.74 |
| | IL1 + Li | C₈H₁₇Si(OCH₃)₃ | 601 | 6.3 | 0.56 | 2.14 |
| | IL1 + Li | none | 587 | 6.4 | 0.52 | 1.96 |
| XXII | Std | C₈H₁₇Si(OCH₃)₃ | 666 | 11.4 | 0.61 | 4.62 |
| | Std | none | 622 | 12.1 | 0.56 | 4.22 |
| | IL1 + Li | C₈H₁₇Si(OCH₃)₃ | 610 | 7.7 | 0.52 | 2.45 |
| | IL1 + Li | none | 574 | 6.7 | 0.47 | 1.82 |

While only certain features of the invention have been illustrated and described herein, many modifications and changes will occur to those skilled in the art. It is, therefore, to be understood that the appended claims are intended to cover all such modifications and changes as fall within the true spirit of the invention.

1. A composition comprising at least one metal complex, said metal complex comprising:
(a) at least one metal atom;
(b) at least one first organic ligand comprising at least one triarylamine group;
(c) at least one second organic ligand comprising at least one acidic group; and
(d) at least one thiocyanate or isothiocyanate ligand.

2. A composition according to claim 1, wherein said at least one metal atom is a metal cation chosen from cations of iron, cations of ruthenium, cations of osmium, cations of technetium, cations of rhodium, and mixtures thereof.

3. A composition according to claim 1, wherein said at least one first organic ligand is chosen from the group consisting of organic ligands having structures I, II, II, IV, V, VI, VII and VIII; 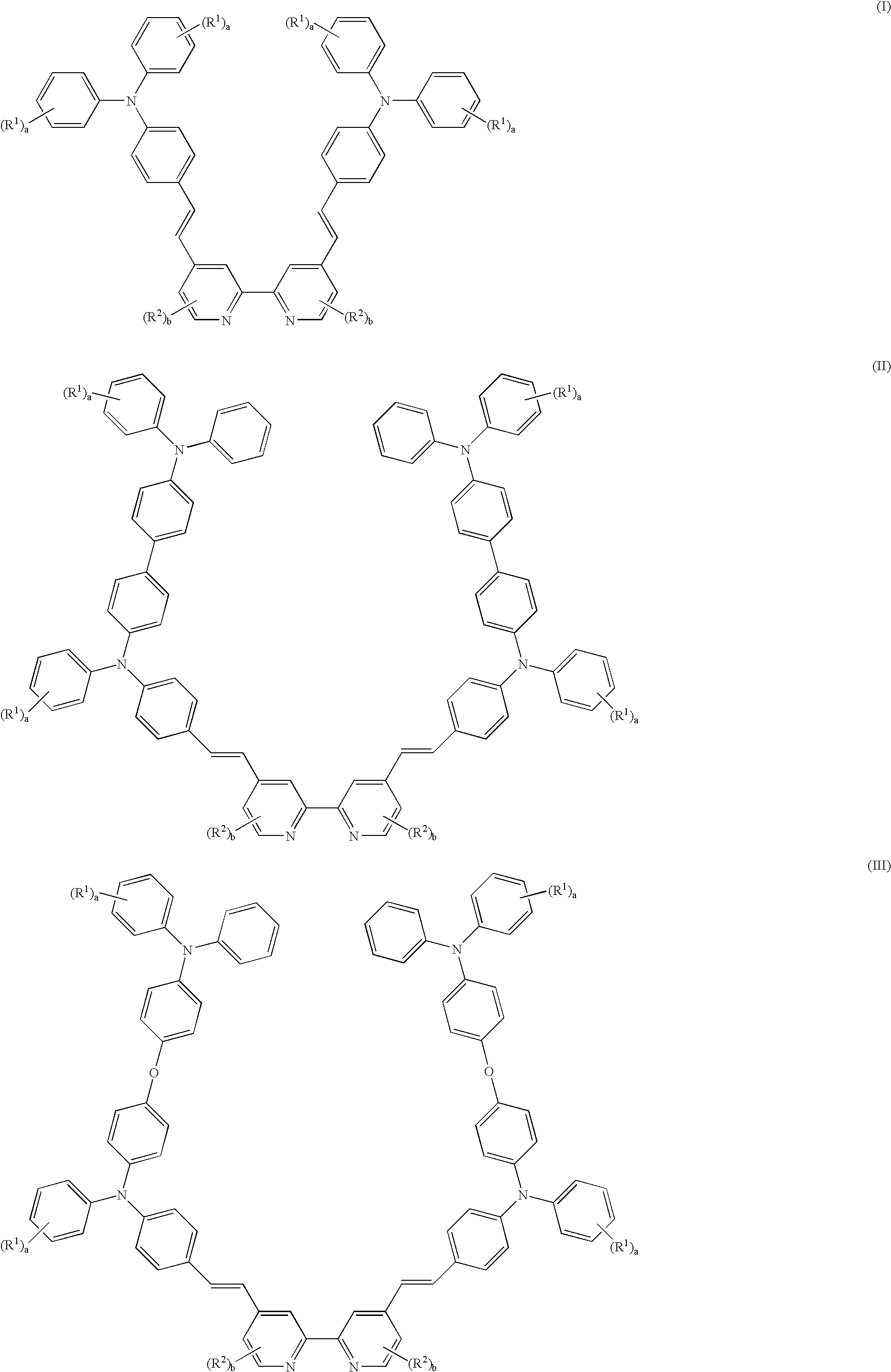 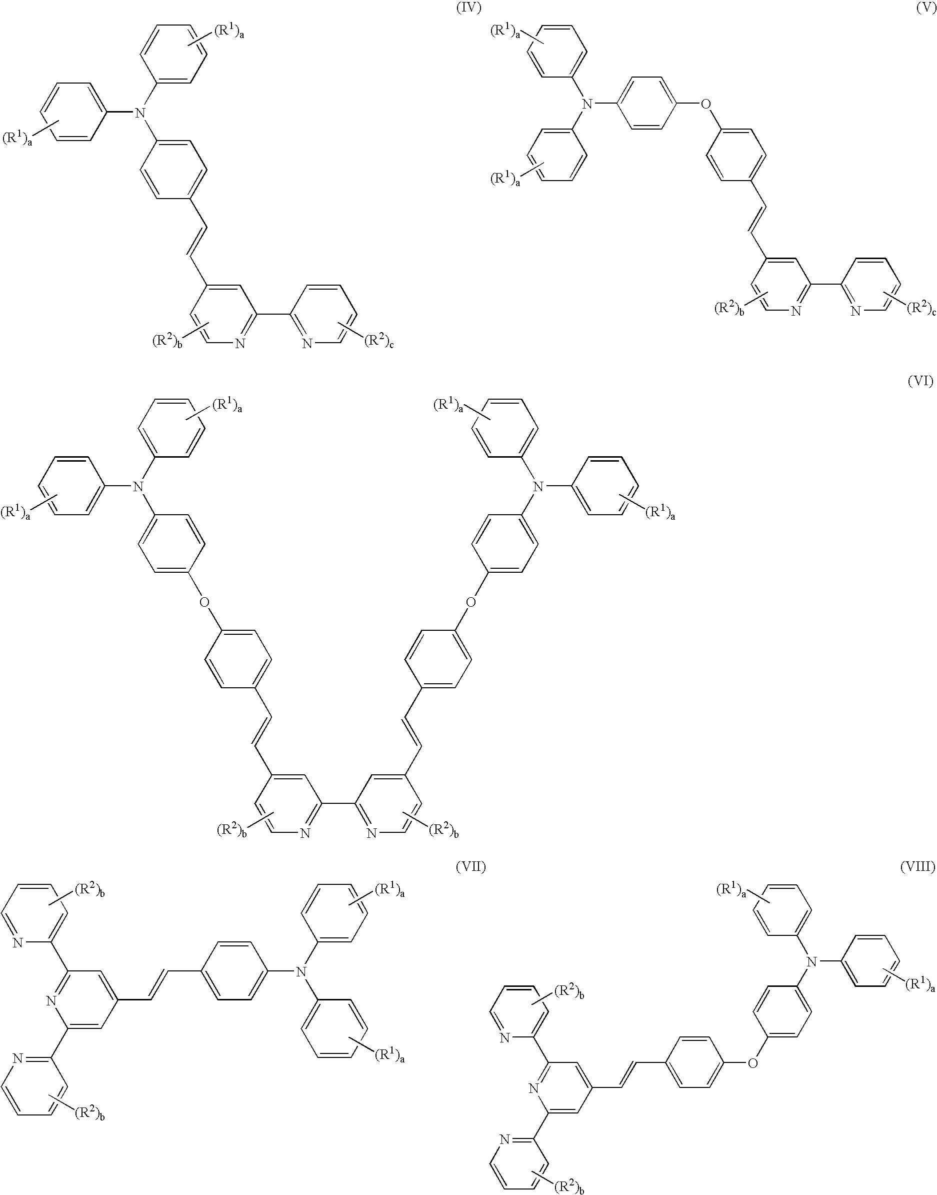
wherein a is independently at each occurence an integer from 0 to 5, b is independently at each occurence an integer from 0 to 3 and c is independently at each occurence an integer from 0 to 4; and R¹ and R² are independently at each occurence a C₁-C₃₀ aliphatic radical, a C₃-C₃₀ aromatic radical, a C₃-C₃₀ cycloaliphatic radical, a halogen atom, a nitro group, a cyano group, a carboxy group, a hydroxyl group, a C₁-C₃₀ alkoxy group, or a triarylamine group.

4. A composition according to claim 1, wherein said at least one acidic group is chosen from carboxylic acid groups, sulfonic acid groups, phosphonic acid groups, sulfinic acid groups, boronic acid groups, their salts, and mixtures thereof.

5. A composition according to claim 1 wherein said second organic ligand has structure XVII; 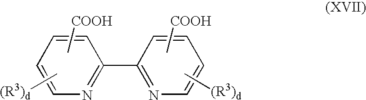
wherein d is independently at each occurrence an integer from 0 to 3; and R³ is independently at each occurrence a halogen atom, a nitro group, a cyano group, a carboxy group, a hydroxyl group, a C₁-C₃₀ aliphatic radical, a C₃-C₃₀ aromatic radical, or a C₃-C₃₀ cycloaliphatic radical.

6. A composition according to claim 1, wherein said at least one metal complex has structure XXI; 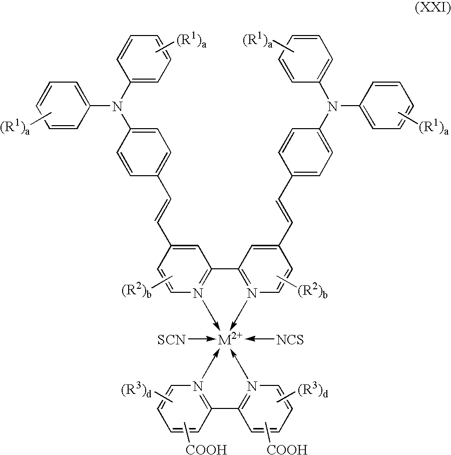
wherein a is independently at each occurrence an integer from 0 to 5, b is independently at each occurrence an integer from 0 to 3, and c and d are independently at each occurrence an integer from 0 to 4; R¹ and R² are independently at each occurence a C₁-C₃₀ aliphatic radical, a C₃-C₃₀ aromatic radical, a C₃-C₃₀ cycloaliphatic radical, a halogen atom, a nitro group, a cyano group, a carboxy group, a hydroxyl group, a C₁-C₃₀ alkoxy group, a C₁-C₃₀ aryloxy group, or a triarylamine group; and R³ is independently at each occurrence a halogen atom, a nitro group, a cyano group, a carboxy group, a hydroxyl group, a C₁-C₃₀ aliphatic radical, a C₃-C₃₀ aromatic radical, or a C₃-C₃₀ cycloaliphatic radical.

7. A composition comprising at least one metal complex, said metal complex comprising
(a) at least one ruthenium cation;
(b) at least one first organic ligand having structure IX; 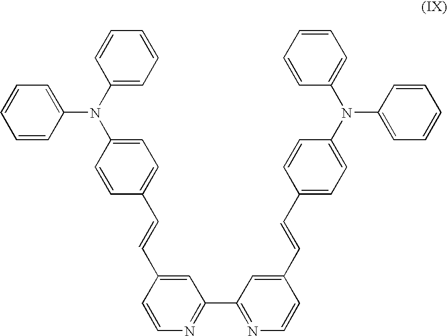
(c) at least one second organic ligand having structure XVIII; and 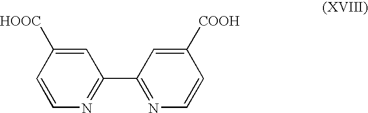
(d) at least two thiocyanate or isothiocyanate ligands.

8. A composition according to claim 7, wherein said at least one metal complex has structure XXII. 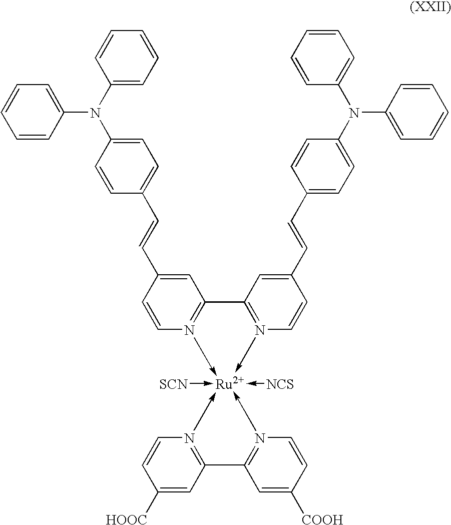
structures I, II, III, IV, V, VI, VII and VIII;

9. A dye-sensitized electrode comprising:
(a) a substrate comprising an electrically conductive surface;
(b) an electron transporting layer disposed on the said electrically conductive surface; and
(c) a composition comprising at least one metal complex disposed on the said electron transporting layer, said metal complex comprising:
(i) at least one metal atom;
(ii) at least one first organic ligand comprising at least one triarylamine group;
(iii) at least one second organic ligand comprising at least one acidic group; and
(iv) at least one thiocyanate or isothiocyanate ligand.

10. A dye-sensitized electrode according to claim 9, wherein said metal atom is a metal cation chosen from cations of iron, cations of ruthenium, cations of osmium, cations of technetium, cations of rhodium, and mixtures thereof.

11. A dye-sensitized electrode according to claim 9, wherein said at least one first organic ligand is chosen from the group consisting of organic ligands having 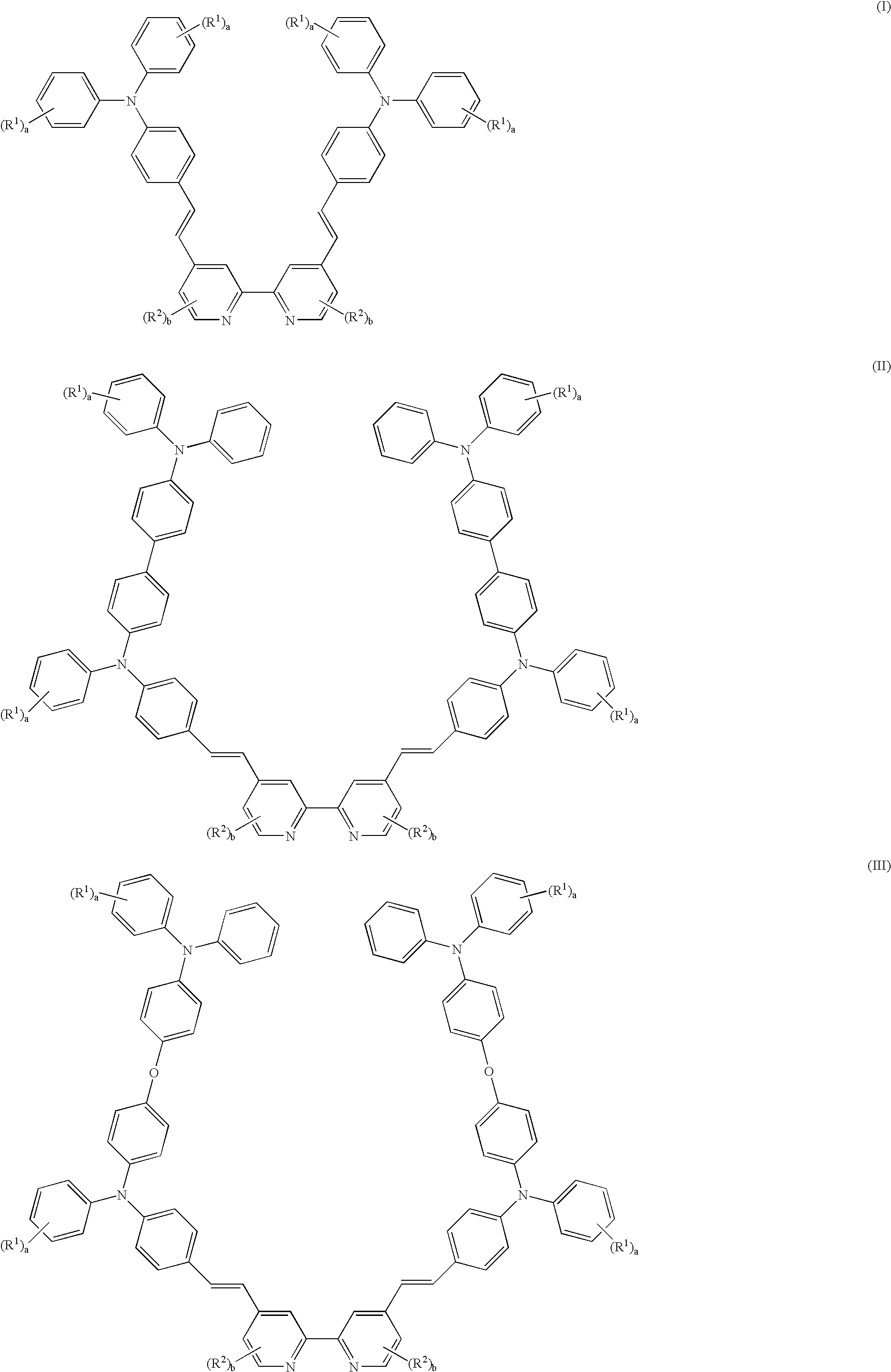 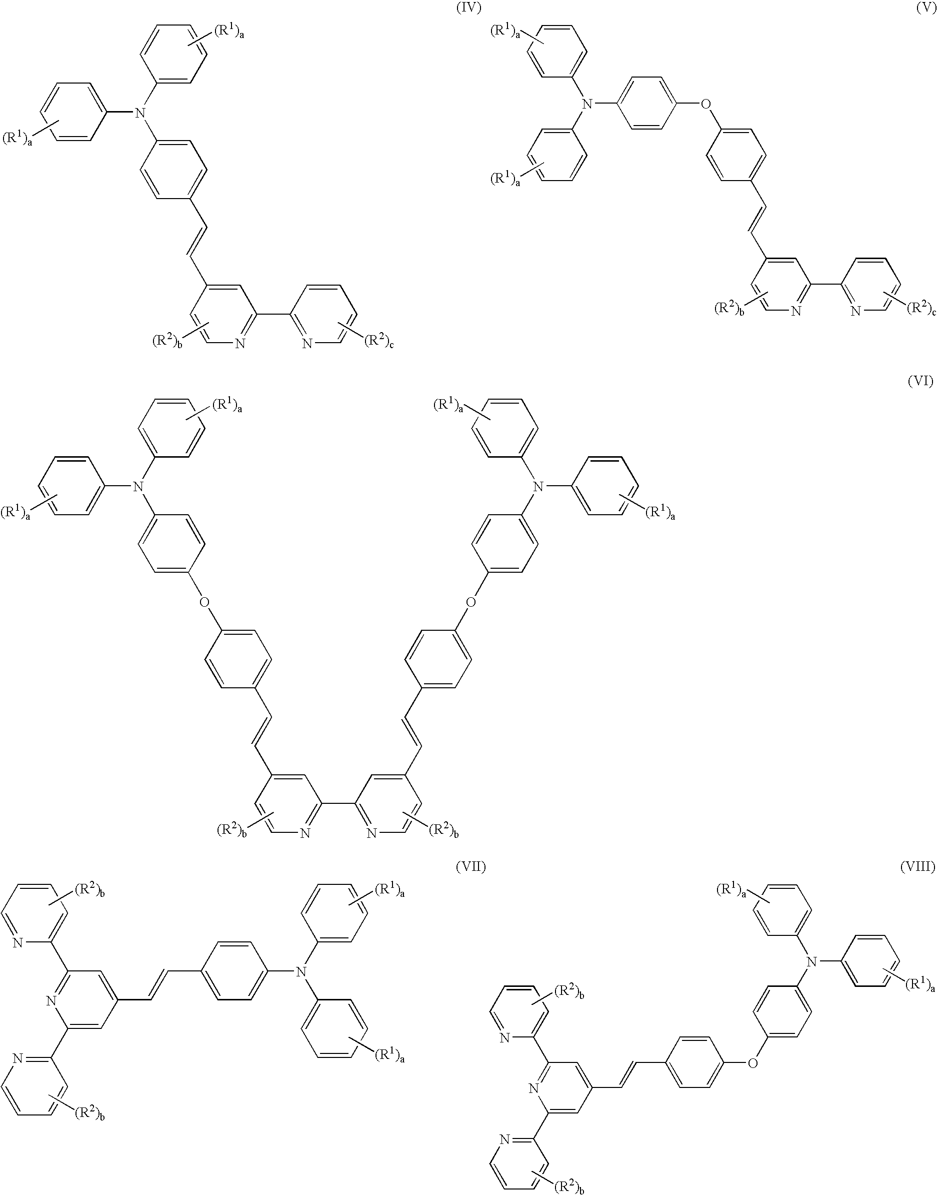
wherein a is independently at each occurence an integer from 0 to 5, b is independently at each occurence an integer from 0 to 3 and c is independently at each occurence an integer from 0 to 4; and R¹ and R² are independently at each occurence a C₁-C₃₀ aliphatic radical, a C₃-C₃₀ aromatic radical, a C₃-C₃₀ cycloaliphatic radical, a halogen atom, a nitro group, a cyano group, a carboxy group, a hydroxyl group, a C₁-C₃₀ alkoxy group, or a triarylamine group.

12. A dye-sensitized electrode according to claim 9, wherein said at least one acidic group is chosen from carboxylic acid groups, sulfonic acid groups, phosphonic acid groups, sulfinic acid groups, boronic acid groups, their salts, and mixtures thereof.

13. A dye-sensitized electrode according to claim 9 wherein said at least one second organic ligand has structure XVII 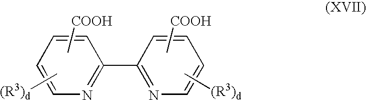
wherein d is independently at each occurence an integer from 0 to 3; and R³ is independently at each occurrence a halogen atom, a nitro group, a cyano group, a carboxy group, a hydroxyl group, a C₁-C₃₀ aliphatic radical, a C₃-C₃₀ aromatic radical, or a C₃-C₃₀ cycloaliphatic radical.

14. A dye-sensitized electrode comprising:
(a) a substrate comprising an electrically conductive surface;
(b) a TiO₂ layer disposed on the said electrically conductive surface; and
(c) a composition comprising at least one metal complex disposed on the said TiO₂ layer, said metal complex comprising:
(i) at least one ruthenium cation;
(ii) at least one first organic ligand having structure IX; 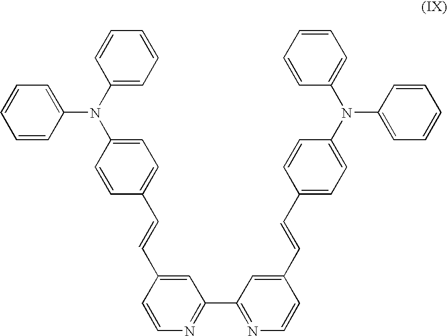
(iii) at least one second organic ligand having structure XVIII; and 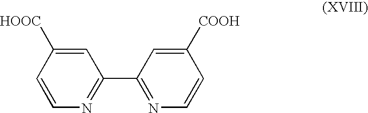
(iv) at least two thiocyanate or isothiocyanate ligands.

15. A solar cell comprising:
(a) a dye-sensitized electrode comprising a substrate comprising an electrically conductive surface; an electron transporting layer disposed on the said electrically conductive surface; and a composition comprising at least one metal complex disposed on the said electron transporting layer, said metal complex comprising:
(i) at least one metal atom;
(ii) at least one first organic ligand comprising at least one triarylamine group;
(iii) at least one second organic ligand comprising at least one acidic group; and
(iv) at least one thiocyanate ligand.
(b) a counter electrode; and
(c) a hole transporting layer contacting with said dye-sensitized electrode and said counter electrode.

16. A solar cell according to claim 15, wherein said metal atom is a metal cation chosen from cations of iron, cations of ruthenium, cations of osmium, cations of technetium, cations of rhodium, and mixtures thereof.

17. A solar cell according to claim 15, wherein said at least one first organic ligand is chosen from the group consisting of organic ligands having structures I, II, III, IV, V, VI, VII and VIII; 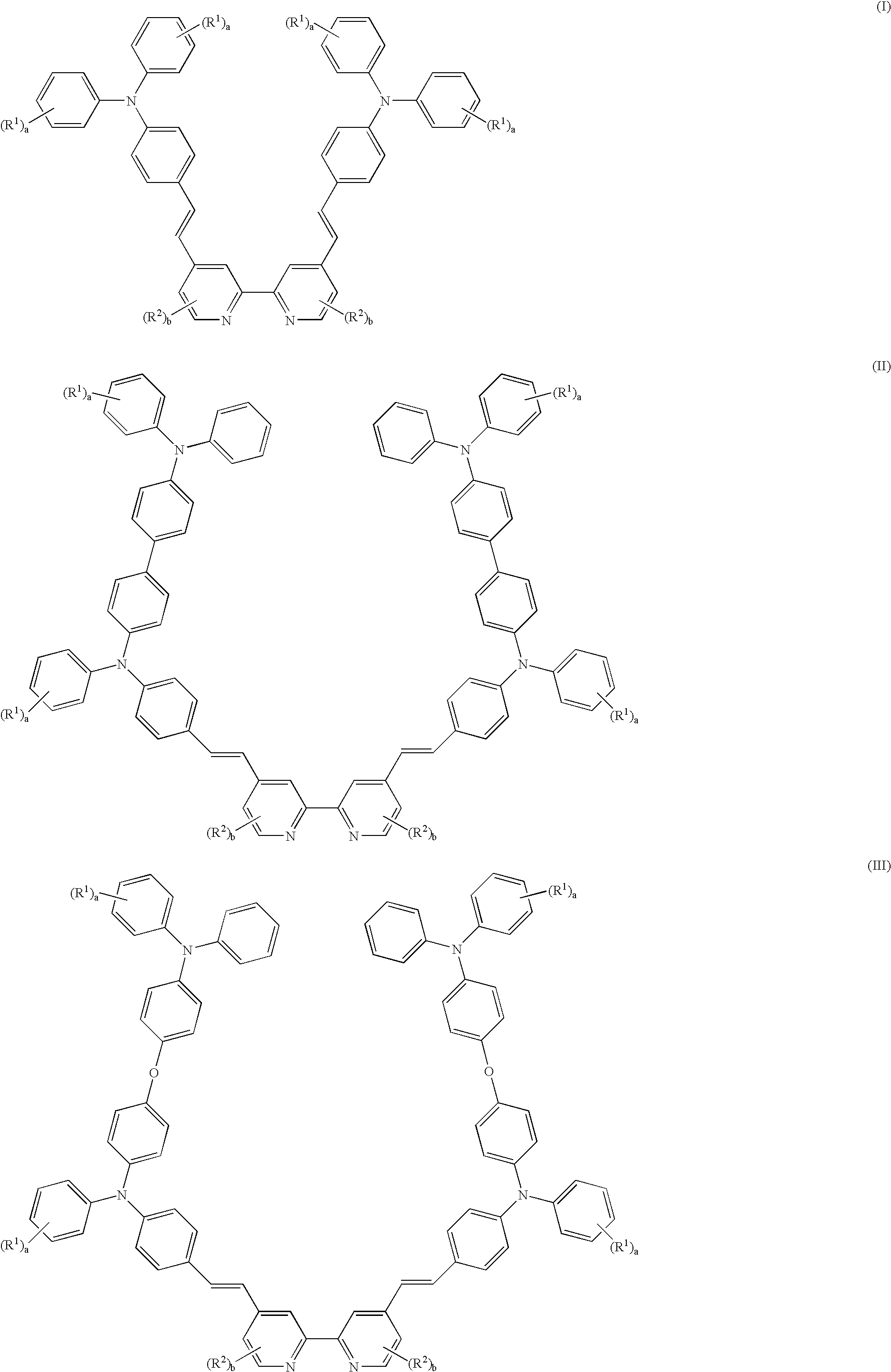 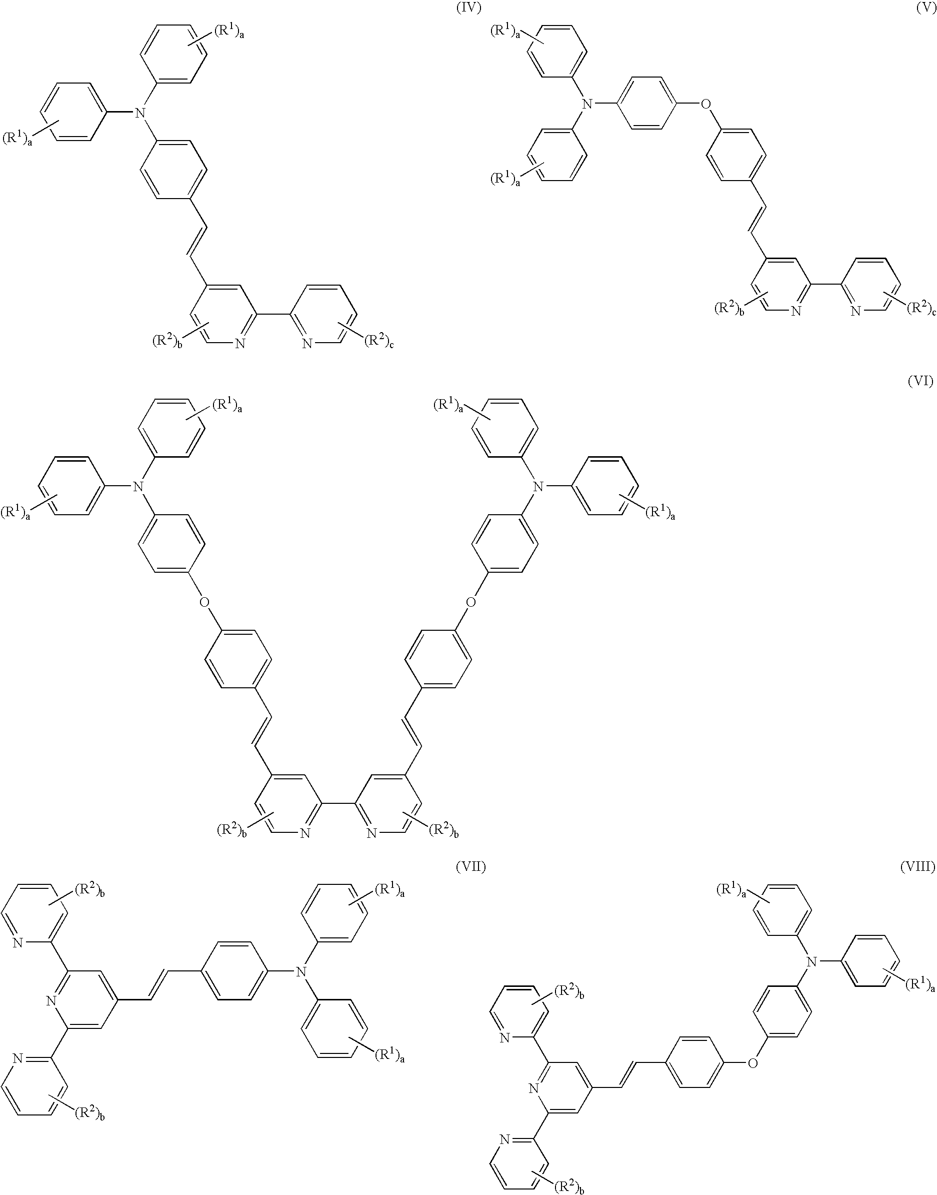
wherein a is independently at each occurence an integer from 0 to 5, b is independently at each occurence an integer from 0 to 3 and c is independently at each occurence an integer from 0 to 4; and R¹ and R² are independently at each occurence a C₁-C₃₀ aliphatic radical, a C₃-C₃₀ aromatic radical, a C₃-C₃₀ cycloaliphatic radical, a halogen atom, a nitro group, a cyano group, a carboxy group, a hydroxyl group, a C₁-C₃₀ alkoxy group, or a triarylamine group.

18. A solar cell according to claim 15, wherein said at least one acidic group is chosen from carboxylic acid groups, sulfonic acid groups, phosphonic acid groups, sulfinic acid groups, boronic acid groups, their salts and mixtures thereof.

19. A solar cell according to claim 15, wherein said at least one second ligand has structure XVII 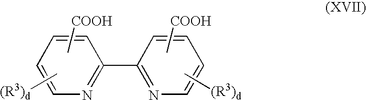
wherein d is independently at each occurence an integer from 0 to 3; and R³ is independently at each occurrence a halogen atom, a nitro group, a cyano group, a carboxy group, a hydroxyl group, a C₁-C₃₀ aliphatic radical, a C₃-C₃₀ aromatic radical, or a C₃-C₃₀ cycloaliphatic radical.

20. A solar cell comprising:
(a) a dye-sensitized electrode comprising a substrate comprising an electrically conductive surface; a TiO₂ layer disposed on the said electrically conductive surface; and a composition comprising at least one metal complex disposed on the said TiO₂ layer, said metal complex comprising:
(i) at least one ruthenium cation;
(ii) at least one first organic ligand having structure IX; 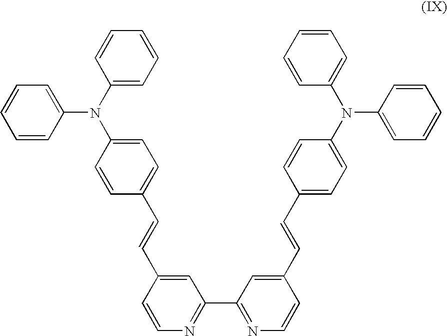
(iii) at least one second organic ligand having structure XVIII; and 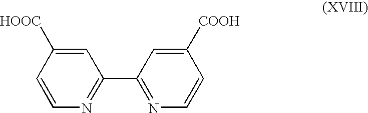
(iv) at least two thiocyanate ligands.
(b) a counter electrode; and
(c) a hole transporting layer contacting with said dye-sensitized electrode and said counter electrode.
